(19) United States
(12) Patent Application Publication
(10) Pub. No.: US 2016/0093420 A1
(43) Pub. Date: Mar. 31, 2016

(54) ARTIFICIALLY-STRUCTURED SUPERCONDUCTING MATERIALS

(71) Applicant: Elwha LLC, Bellevue, WA (US)

(72) Inventor: YAROSLAV A. URZHUMOV, BELLEVUE, WA (US)

(21) Appl. No.: 14/865,450

(22) Filed: Sep. 25, 2015

Related U.S. Application Data
(60) Provisional application No. 62/056,253, filed on Sep. 26, 2014.

(51) Int. Cl. H01B 12/02; H01L 39/02; H01L 39/24

(52) U.S. Cl. CPC H01B 12/02; H01L 39/24; H01L 39/02

(57) ABSTRACT

A composite medium may be artificially structured to enhance electron-phonon coupling in the composite medium, whereby to enhance a Cooper pairing instability in the composite medium. This yields a composite superconductor with superconducting properties (energy gap, critical temperature, etc.) more robust than the superconducting properties of the constituent media. The electron-phonon coupling may be enhanced by increasing the phononic density of states in the composite medium, by introducing hyperbolic phononic dispersion, phononic van Hove singularities, and/or reduced phonon group velocities.

If an Application Data Sheet (ADS) has been filed on the filing date of this application, it is incorporated by reference herein. Any applications claimed on the ADS for priority under 35 U.S.C. §§119, 120, 121, or 365(c), and any and all parent, grandparent, great-grandparent, etc. applications of such applications, are also incorporated by reference, including any priority claims made in those applications and any material incorporated by reference, to the extent such subject matter is not inconsistent herewith.

### CROSS-REFERENCE TO RELATED APPLICATIONS

The present application claims the benefit of the earliest available effective filing date(s) from the following listed application(s) (the “Priority Applications”), if any, listed below (e.g., claims earliest available priority dates for other than provisional patent applications or claims benefits under 35 USC §119(e) for provisional patent applications, for any and all parent, grandparent, great-grandparent, etc. applications of the Priority Application(s)).

### Priority Applications

The present application claims benefit of priority of U.S. Provisional Patent Application No. 62/056,253, entitled ARTIFICIALLY STRUCTURED SUPERCONDUCTING MATERIALS, naming YAROSLAV A. URZHUMOV as inventor(s), filed Sep. 26, 2014, which was filed within the twelve months preceding the filing date of the present application or is an application of which a currently co-pending priority application is entitled to the benefit of the filing date.

If the listings of applications provided above are inconsistent with the listings provided via an ADS, it is the intent of the Applicant to claim priority to each application that appears in the Domestic Benefit/National Stage Information section of the ADS and to each application that appears in the Priority Applications section of this application.

All subject matter of the Priority Applications and of any and all applications related to the Priority Applications by priority claims (directly or indirectly), including any priority claims made and subject matter incorporated by reference therein as of the filing date of the instant application, is incorporated herein by reference to the extent such subject matter is not inconsistent herewith.

### REFERENCES

1. Urzhumov et al, Phys. Rev. E 72, 026608 2005, “Extreme anisotropy of wave propagation in two-dimensional photonic crystals.”

2. Jacob et al, Appl. Phys. B (2010) 100: 215-218, “Engineering photonic density of states using metamaterials.”

3. C. Poole et al, “Superconductivity”, 2nd edition, Associated Press, 2007.

4. Zen et al, Nature Comm. , “Engineering thermal conductance using a 2D phononic crystal”; DOI: 10.1038/ncomms4435.

5. David & Hussein, “Nanophononic metamaterial: Thermal conductivity reduction by local resonance”, arXiv:1304.6070v3 [cond-mat.mtrl-sci] 30 Jul. 2013.

6. Van Dyke et al., “Direct evidence for a magnetic f-electron-mediated pairing mechanism of heavy-fermion superconductivity in CeCoIn5”, PNAS 2014 111 (32) 11663-11667; DOI:10.1073/pnas.1409444111.

7. P. Aynajian, Electron-Phonon Interaction in Conventional and Unconventional Superconductors, Springer Theses, Springer-Verlag, Berlin Heidelberg, 2010. DOI: 10.1007/978-3-642-14968-9_1.

8. S. Fujita et al., Quantum Theory of Conducting Matter: Superconductivity, Springer 2009. DOI 10.1007/978-0-387-88211-6.

9. BCS: 50 years/edited by Leon N. Cooper and Dmitri Feldman. World Scientific, 2010.

10. X. Zhang et al., “Heirarchical Porous Plasmonic Metamaterials for Reproducible Ultrasensitive Surface-Enhanced Raman Spectroscopy,” Adv. Mater. 2015, 27, 1090-1096.

11. I. Staude et al., “Hybrid High-Resolution Three-Dimensional Nanofabrication for Metamaterials and Nanoplasmonics,” Adv. Mater. 2013, 25, 1260-1264.

12. J. Henzie et al., “Nanofabrication of Plasmonic Structures,” Annu Rev. Phys. Chem. 2009.60:147-165.

13. J. Henzie et al, “Multiscale patterning of plasmonic metamaterials,” Nature Nano. 2 (2007), 549-554.

14, S. Shinde and G. Srivastava, eds., Length-Scale Dependent Phonon Interactions, Springer, 2014.

All of the above references are herein incorporated by reference to the extent that they are not inconsistent with the present disclosure.

### BACKGROUND

The relationship between the superconducting energy gap at zero temperature, Δ(0), and the critical temperature of a superconducting state, T_{c}, is well established through the BCS microscopic theory of superconductivity. An increase in Δ(0), a fundamental property of a superconducting medium leads to an increase in the application-relevant properties of superconductors, such as the critical current density (J_{c}), critical magnetic field (B_{c}), and the critical temperature (T_{c}). Increasing the critical current density and/or critical magnetic field is useful for industrial applications of superconductors, such as superconducting magnets. Superconducting magnets with higher J_{c} or B_{c} are highly desirable, since they can generate stronger magnetic fields. The strength of magnetic field is a critical performance metric for magnetic resonance imaging (MRI) magnets, confined fusion reactors (tokamaks), particle accelerator magnets, magnetic levitation vehicles and in other industrial uses of magnetic fields. An increase of the critical temperature of the superconducting state results in energy and cost savings for the superconductor cooling systems.

Embodiments combine two or more elementary or molecular materials into a composite nanomaterial whose Δ(0) is greater than Δ(0) in either of the materials used. Specific mechanisms for achieving this enhancement by virtue of having a larger spectrally-averaged phononic density of states than the same quantity in either of the elementary materials used are being presented here for the first time.

BCS Theory of Superconductivity.

The BCS theory is the only widely accepted microscopic theory of superconductivity, capable of expressing the macroscopic properties of superconductors, such as their critical temperature, through the microscopic parameters relating to the dynamics of elementary excitations in the solid. The theory is founded on two cornerstones: one is the formation of electron-electron pairs (Cooper pairs) by virtue of an attractive interaction, which in the classical BCS theory is postulated as an exchange of virtual phonons between the interacting electrons. A generalized BCS theory may include other elementary excitations as contributors to the attractive potential describing effective electron-electron coupling, in addition to the phonon exchange mechanism. Even in such generalized BCS theories, phonon exchange mechanism must still be included as an important contributor to the effective potential. In fact, it is considered proven that the phonon-mediated interaction is always attractive (Reference 8).

Cooper pairs, unlike single electrons, obey Bose statistics. The other cornerstone of the BCS theory is that, at sufficiently low temperatures, a fraction of the Cooper-pair bosons experience Bose-Einstein condensation into the ground state. This condensate behaves macroscopically as a superfluid. Since Cooper bosons carry electric charge of −2 e, their condensate exhibits electrical conduction without resistance.

While there has been a continuing discussion on the microscopic mechanisms of the attractive interaction between electrons in superconductors, there is presently no doubt that the two above-mentioned cornerstones are the basis of superconductivity in all known instances.

Regarding the microscopic mechanisms of the attractive interaction in Cooper pairs, there have been suggestions that electron-phonon interactions alone cannot explain all of the features of high-temperature superconductors based on copper oxides. Various other mechanisms have been proposed, including spin-mediated attraction in antiferromagnetic superconductors, f-electron mediated interactions in heavy-fermion superconductors, and other exotic exciton, polaron and plasmon-mediated couplings. Superconducting media where no scientific consensus exists on the dominant microscopic mechanisms of the attractive interaction may be referred to as Class-2 superconductors; common examples of Class-2 superconductors are copper oxides and their complexes with other metals, heavy fermion metals and composites, (Fe,Ni) oxypnictides, iron chalcogenides, and some organics. What we refer to as Class-1 superconductors, on the contrary, are believed to be completely explainable in terms of the pure phonon-based BCS theory; Class-1 superconductors include all elementary metals, magnesium diboride, fullerene, graphene and other carbon-based superconductors, and some organic materials. For a handful of simple materials, such as crystalline silicon modifications and MgB2, ab initio calculations were performed based on the BCS theory, which yielded T_{c} calculations in excellent agreement with experimental measurements. Moreover, in the case of high-pressure allotropic modifications of Si, BCS theory-based calculations provided definitive predictions that these previously unobserved forms of Si must be superconductors, and estimates of T_{c} and its pressure dependence (Reference 9, page 384).

Thus, presently there is no doubt that phonon-mediated interaction contributes to the attractive e-e potential in all crystalline superconductors, including both Class-1 and Class-2 (see, e.g., Reference 7 and the introductory discussion in Chapter 1 therein). Furthermore, as proven by the Fröhlich theory, the phonon-mediated interaction between electrons is always attractive, for any virtual phonon whose energy exceeds the electron energy difference before and after the transition. The so-called Fröhlich Hamiltonian (Reference 8) leads to the following effective phonon exchange interaction:

$${V}_{eff} = {\vert V ( q ) \vert}^{2} \frac{{ℏω}_{q}}{{( {ε}_{k + q} - {ε}_{k} )}^{2} - {( {ℏω}_{q} )}^{2}} ,$$

where [symbol] ω_{q} is the energy of a virtual phonon with momentum q. This potential is always negative and thus the interaction is attractive, as long as |ε_{k+q}−εₖ|< [symbol] ω_{q}. Note that the energy and momentum of phonons need not satisfy the phonon dispersion relation in the case of virtual phonons.

Pairs of electrons whose energy difference is zero, or at least much less than the Debye frequency, are abundant in any conducting crystal: the condition of zero energy difference, ε_{k+q}−εₖ=0, corresponds to the exchange momentum q being parallel to the electron energy (Fermi) surface. Therefore, virtual phonons always lead to an attractive interaction for those electron pairs. Virtual phonons are available in the amounts proportional to the phononic density of states. Consequently, increasing the strength of this interaction can only lead to an increase in the Cooper pair binding energy. This notion, fully supported by the scientific models that successfully predict the properties of Class-1 superconductors (see Reference 9, page 384) is the foundation for our invention.

In the original BCS theory (References 3, 7), the attractive interaction is crudely modeled with a piecewise-constant attractive potential, V₀, which absorbs any details of the attractive interaction mediated by phonons, as well as any residual electrostatic repulsion. The theory connects this interaction energy to the zero-temperature superconducting gap,

$$Δ ( 0 ) = 2 {ℏΩ}_{D} exp ( - \frac{1}{N ( {E}_{F} ) {V}_{0}} ) ,$$

and the zero-field critical temperature,

$${T}_{c} = 0.57 Δ ( 0 ) = 1.14 {ℏΩ}_{D} exp ( - \frac{1}{N ( {E}_{F} ) {V}_{0}} ) .$$

Here, N(E_{F}) is the electronic density of states at the Fermi level, and Ω_{D} is the Debye frequency, which is defined as the maximum frequency a phonon can have in an atomistic lattice. In a simple monoatomic cubic lattice with lattice constant a, the Debye frequency corresponds to a phonon wavelength of 2a. The Debye frequency is often expressed as the Debye temperature, Θ_{D}= [symbol] Ω_{D}/k_{B}.

A discussion of the Eliashberg extension to the original BCS theory of superconductivity can be found in, e.g., References 3 and 7. Equation 7.96 on page 187 of Reference 3 gives the dimensionless electron-phonon coupling constant (λ) in terms of the phononic density of states Dₚₕ(ω) and the electron-phonon vertex function a(ω):

λ=2∫₀¹⁰⁶ ^{_{D}}dω ω⁻¹α²(ω)Dₚₕ(ω).

In the above equation, we have changed the upper integration limit from infinity to include the finite Debye frequency. The BCS theory then yields a relationship between the electron-phonon coupling strength λ and the superconducting energy gap

$$Δ ( 0 ) = 2 {ℏω}_{c} exp ( \frac{λ - μ}{λ + 1} ) ,$$

where μ is a correction that accounts for residual screened Coulomb repulsion between the electrons. In the Eliashberg formalism, the phonon-mediated attraction and the Coulomb repulsion are accounted for individually by virtue of these two interaction strength constants, λ and μ.

The crucial feature of both the original BCS and the Eliashberg extensions is that the superconducting gap and T_{c} increase rapidly with the increasing strength of phonon-mediated attractive interaction.

### SUMMARY

The Eliashberg extension of the Bardeen-Cooper-Schrieffer (BC S) theory establishes a relationship between the superconducting (SC) energy gap and the phononic properties of the crystal. Specifically, the SC energy gap increases with the increasing spectral integral over the phononic density of states (PDoS). We propose to increase PDoS, averaged over the relevant portion of the phonon spectrum, by virtue of a nanostructured medium—a superlattice of at least two different materials periodic in at least one dimension. Such superlattices or metamaterials can be designed to provide a hyperbolic dispersion isosurfaces in the energy-momentum space. The consequence of the hyperbolic dispersion is the increase in the PDoS, which occurs by virtue of the increase in the volume of the Brillouin zone where the group velocity is small. In certain phonon frequency ranges, such media have a substantially larger number of unique phonon states (distinguished by their momenta and polarizations) with a low group velocity, than a normally-dispersive medium. Low group velocity allows one to pack more unique phonon states into a given frequency interval, leading to strengthened phonon-mediated interactions between electrons, and consequently stronger Cooper pairs.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIG. 1A depicts phonon isofrequency surfaces for a non-hyperbolic phononic medium.

FIG. 1B depicts phonon isofrequency surfaces for a hyperbolic phononic medium.

FIG. 2 depicts a phononic band structure and a corresponding phononic density of states.

FIG. 3A depicts a composite superconductor that is artificially structured in one dimension.

FIG. 3B depict a composite superconductor that is artificially structured in two dimensions.

FIG. 3C depict a composite superconductor that is artificially structured in three dimensions.

FIG. 4 depicts a composite superconductor that is composed of three materials.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

We disclose here several approaches for increasing the phononic density of states (PDoS) in an artificially-structured composite. The phononic density of states is not to be confused with the electronic density of states, often abbreviated to simply “the density of states,” which is another parameter in the BCS theory of superconductivity. It is also not to be confused with the photonic density of states, which is referenced in this document only in the context of an analogy between photon and phonon waves, to the extent that this analogy applies.

In one approach, PDoS enhancement originates from a hyperbolic dispersion relation, and it occurs in a relatively broad phonon frequency band where such form of dispersion exists. A dispersion relation may be used to characterize wave propagation in effective media (phononic metamaterials) as well as in periodically arranged structures (phononic crystals). In an effective medium context, the effective medium has one or more constitutive parameters (density and/or elastic modulus) that are tensor indefinite, i.e. positive in one direction and negative in another direction. In either a phononic metamaterial or phononic crystal context, a hyperbolic dispersion relation describes a situation where phonon propagation is allowed in at least one direction yet prohibited in at least one other direction.

For sufficiently small wavevectors, an ordinary, non-hyperbolic medium with an orthotropic crystalline lattice typically has at least one phonon dispersion branch having a dispersion relation of the form

cₓ²kₓ²+c_{y}²k_{y}²+c_{z}²k_{z}²=ω²,

where c_{x,y,z} are positive real numbers, so that the isofrequency surfaces are ellipsoids, spheroids or spheres, as shown in FIG. lA for a 2D reduction. On the other hand, a hyperbolic medium might have a dispersion relation of the form

k_{z}²−k_{y}²+k_{z}²=ω²/v²

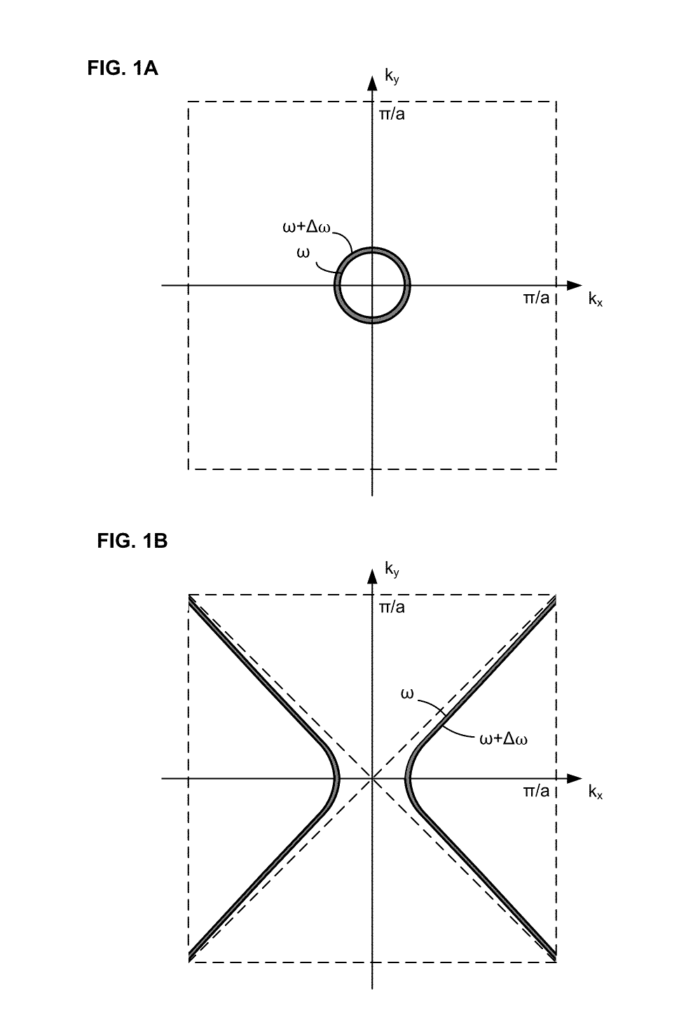

so that the isofrequency surfaces are hyperboloids, as shown in FIG. 1B for a 2D reduction. The density of states having frequencies between ω and ω+Δω is given by the volume enclosed between the isofrequency surfaces for frequencies ω and ω+Δω, represented as the shaded areas in FIGS. lA and 1B. Because the sphere (or ellipsoid) is a bounded, compact surface while the hyperboloid is not, it will be appreciated that the hyperbolic dispersion relation therefore gives rise to a very large density of states. Indeed, the relevant extent of the hyperboloidal isofrequency surface is bounded only by the applicable maximum wavevector, which is about π/α for an artificially-structured superlattice having a lattice constant a (more generally, we truncate the hyperboloid within a single Brillouin zone of the superlattice). Thus, for a medium that is artificially-structured with a superlattice spacing a to provide hyperbolic dispersion at a frequency co, the density of states is of order (π/α)²/ω. This equation reveals that the PDoS of a hyperbolic medium can be dramatically increased by decreasing the length scale a of the artificially-structured superlattice.

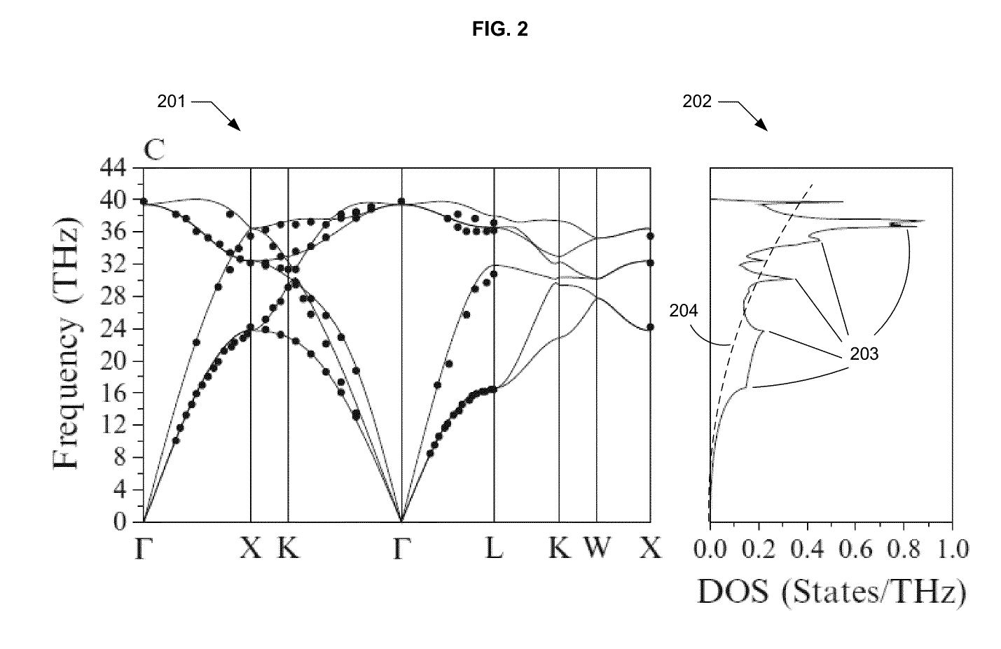

In another approach, very strong PDoS enhancement occurs in one or more specific ranges of phonon frequencies, where each specific range is centered upon and associated with a singularity of phononic density of states. In the electronic band theory of crystalline solids, the singularities in the electronic density of states are known as van Hove singularities. Similar singularities occur in the photonic density of states in photonic crystals, e.g. as described in Ref 1. Here, embodiments exploit analogous van Hove singularities in the phononic density of states, which correspond to frequencies at which the phonon group velocity vanishes. An illustrative phononic density of states is depicted in FIG. 2, which shows an ab initio calculation of phonon band structure 201 and density of states 202 for carbon in the diamond structure (adapted from FIG. 1.2 of Ref 13). The figure illustrates that a phononic density of states can include numerous van Hove singularities 203, with a Debye model of the phononic density of states shown as the dashed line 204 on the same graph to illustrate that van Hove singularities 203 can be exploited to enhance the phononic density of states relative to the Debye model.

It will be appreciated that the phononic density of states can be enhanced in a van Hove fashion even if the phononic density of states does not become strictly singular at a particular frequency. For example, the phononic density of states can be enhanced by a reduction of the group phonon group velocity in one or more specific frequency ranges. This is illustrated in FIG. 2, where frequency domains of small slope in the band structure correspond to frequency domains of small group velocity, which in turn correspond to frequency domains of enhanced phononic density of states.

It will be further appreciated that the enhanced phononic density of states due to small or zero group velocity can coincide with an enhanced phononic density of states due to hyperbolic dispersion. In general, the density of states is given by the equation

$$ρ ( ω ) = {\sum }_{n} {\int }_{[ {ω}_{n} ( \vec{k} ) = ω ]} \frac{1}{\vert {\vec{v}}_{g} ( \vec{k} ) \vert} d {S}_{\vec{k}}$$

which expresses the density of states at a selected frequency as an integral of the inverse magnitude of the group velocity over the isofrequency surfaces for the selected frequency, summed over all branches of dispersion existing at that frequency. When a range of small or zero group velocity coincides with a range of hyperbolic dispersion, there is an additive enhancement of the phononic density of states.

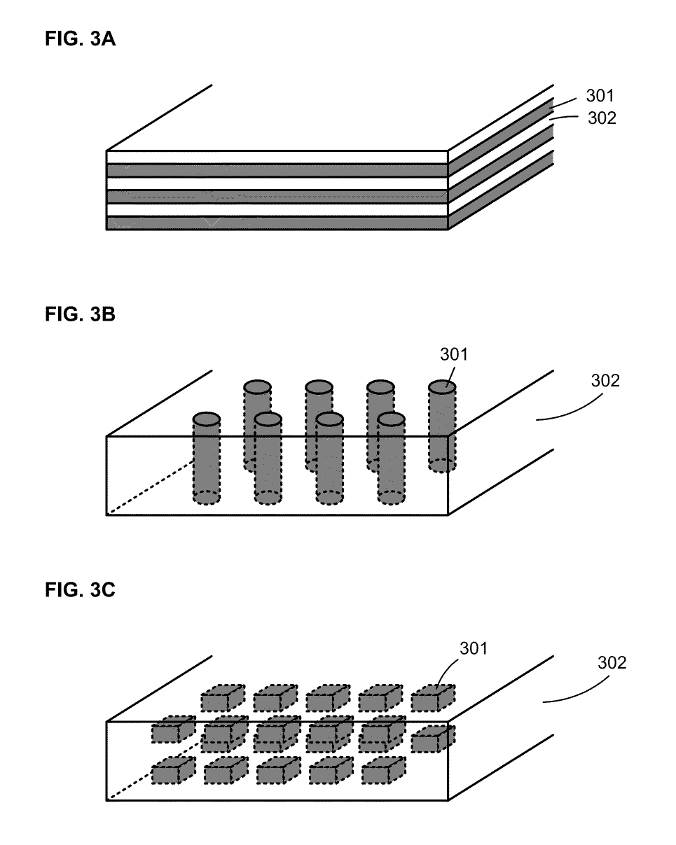

Turning to a description of the structures that enhance the phononic density of states, embodiments provide a composite medium that is artificially structured to enhance electron-phonon coupling in the composite. For example, the composite medium may be artificially structured in one spatial dimension, e.g. by interleaving layers of a first material 301 and a second material 302 as depicted in FIG. 3A. Alternatively, the composite medium may be artificially structured in two spatial dimensions, e.g. as rods of a first material 301 embedded in a second material 302 as depicted in FIG. 3B. While the rods are here depicted as solid right circular cylinders in a square array, this depiction is merely schematic and is not intended to be limiting; in various embodiments, the rods can be right or oblique, solid or hollow, circular or non-circular (such as polygonal or elliptical), etc., and they can be arranged in various regular or irregular arrays (such as a 2D Bravais lattice or a random or quasi-crystalline array). Alternatively, the composite medium may be artificially structured in all three spatial dimensions, e.g. as portions or droplets of a first material 301 embedded in a second material 302 as depicted in FIG. 3C. While the portions or droplets are here depicted as discrete cubes in a cubic array, this depiction is merely schematic and is not intended to be limiting: in various embodiments, the droplets can be solid or hollow; they can assume various shapes including spheres, spheroids, cubes, cuboids, polyhedra, etc.; they can be discrete or interconnected between adjacent unit cells; and they can be arranged in various regular or irregular arrays (such as a 3D Bravais lattice or a random or quasi-crystalline array).

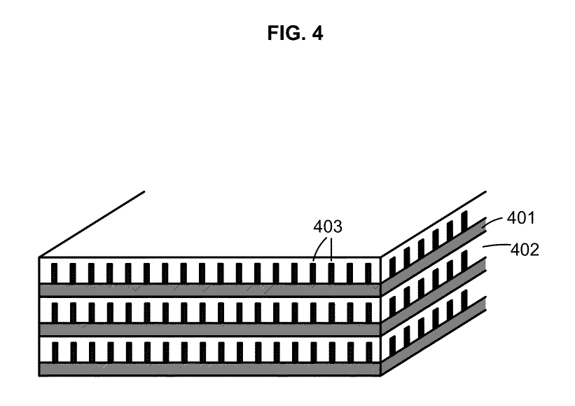

While FIGS. 3A-3C depict binary composites that are composed of only first and second materials 301 and 302, this is not intended to be limiting and other embodiments provide an artificially-structured composite medium that is composed of three or more materials. An example is shown in FIG. 4, which depicts a layered structure with alternating layers of first and second materials 401 and 402, with pillars of a third material 403 arranged on the upper surface of each layer of the first material 401 and embedded in each layer of the second material 402.

In some approaches, the constituent materials (e.g. the first and second materials 301 and 302 in FIGS. 3A-3C, or the first, second, and third materials in FIG. 4) are pure substances such as elemental or molecular solids. In other approaches, one or more of the constituent materials are themselves composite materials. Throughout this disclosure, whenever a constituent material or its bulk properties are discussed, it is contemplated that the constituent material could itself be a composite material, with its bulk properties then being composite properties of the composite material. For example, a constituent material could itself be a metamaterial, with its bulk properties then being the effective properties of the metamaterial.

The electron-phonon coupling is enhanced in the sense that a composite electron-phonon coupling constant for the composite medium is substantially greater than a bulk electron-phonon coupling constant for one or more constituent materials (e.g. the first and second materials 301 and 302 in FIGS. 3A-3C, or the first, second, and third materials in FIG. 4). Thus, for example, if the first and second constituent materials have bulk electron-phonon coupling constants λ⁽¹⁾ and λ⁽²⁾ defined as

λ^{(1,2)}=2∫₀^{Ω}^{_{D}}dω ω⁻¹α²(ω)Dₚₕ^{(1,2)}(ω),

where Dₚₕ⁽¹⁾(ω) is the spectral density of phonons in a bulk medium composed of the first material, Dₚₕ⁽²⁾(ω) is the spectral density of phonons in a bulk medium composed of the second material, and α(ω) is the electron-phonon vertex function (ignoring its medium dependence), then the composite medium has a composite electron-phonon coupling constant λ^{(C)} defined as

λ^{(C)}=2∫₀^{Ω}^{_{D}}dω ω⁻¹α²(ω)Dₚₕ^{(C)}(ω),

where Dₚₕ^{(C)}(ω) is the spectral density of phonons in the composite medium, and the composite medium is artificially structured so that λ^{(C)}>λ⁽¹⁾ and/or λ^{(C)}>λ⁽²⁾. As these equations reveal, the composite electron-phonon coupling can be enhanced by increasing the integrated spectral density of phonons in the composite medium relative to the integrated spectral density of phonons in one or more of the constituent materials.

In some approaches, the composite electron-phonon coupling constant λ^{(C)} exceeds the smallest of the bulk electron-phonon coupling constants λ⁽¹⁾, λ⁽²⁾, etc. for the constituent media. For example, the composite electron-phonon coupling constant λ^{(C)} might be about 1%, 2%, 5%, 10%, 20%, or 50% greater than the smallest of the bulk electron-phonon coupling constants λ⁽¹⁾, λ⁽²⁾, etc. for the constituent media. In other approaches, the composite electron-phonon coupling constant λ^{(C)} exceeds the largest of the bulk electron-phonon coupling constants λ⁽¹⁾, λ⁽²⁾, etc. for the constituent media. For example, the composite electron-phonon coupling constant λ^{(C)} might be about 1%, 2%, 5%, 10%, 20%, or 50% greater than the smallest of the bulk electron-phonon coupling constants λ⁽¹⁾, λ⁽²⁾, etc. for the constituent media.

Typical embodiments provide a composite material that is artificially structured to have a superlattice spacing on the order of 1 to 100 nm. Various nanofabrication techniques are capable of delivering resolution at this length scale, including extreme UV lithography; multi-patterning photolithography; electron-beam lithography; proton- or ion-beam lithography; scanning probe lithography; multiphoton or direct laser lithography (i.e. to make polymer templates), nanoimprint lithography; magnetolithography (especially for incorporating constituent materials that are ferromagnetic or strongly paramagnetic); self-assembly of nanoparticles; and various thin-film deposition techniques, including chemical vapor deposition (CVD), physical vapor deposition (PVD), and atomic layer deposition (ALD). In some approaches, a 3D material may be fabricated by iterating one or more surface nanofabrication techniques for successive 2D layers of the composite. Various nanofabrication techniques have been employed to create nano-scale metamaterials. Ref. 10, for example, describes a porous gold metamaterial fabricated by lyotropic liquid crystal (LLC) templating; Ref 11 describes 3D nanofabrication of various metamaterials and nanoplasmonics; and Refs. 12 and 13 describe nanohole and nanopillar arrays fabricated by soft interference lithography.

In some approaches, the composite medium includes a first constituent material that is a bulk superconducting material, and a second constituent material that is not a bulk superconducting material, and by virtue of the enhanced electron-phonon coupling in the composite medium, the composite medium becomes a superconductor with an superconducting energy gap greater than the superconducting energy gap of the bulk superconducting material. In other approaches, the composite medium includes two different bulk superconducting materials, and by virtue of the enhanced electron-phonon coupling in the composite medium, the composite medium becomes a superconductor with an superconducting energy gap greater than the superconducting energy gap in either of the two bulk superconducting materials. In yet other approaches, the composite medium includes two bulk non-superconducting materials, yet by virtue of the enhanced electron-phonon coupling the composite medium, the composite medium becomes a superconductor with a superconducting energy gap.

While the approaches of the previous paragraph describe the composite superconducting medium in terms of its superconducting energy gap at zero temperature, it will be appreciated that by enhancing the Cooper pairing instability in the composite medium by increasing electron-phonon coupling in the composite medium, other relevant and useful properties of the composite superconducting medium are enhanced. For example, an increased superconducting energy gap at zero temperature corresponds to an increased critical temperature, so the composite superconductor can be used in applications where it is inconvenient to cool the superconductor to the lower critical temperatures of the constituent bulk superconductor. It also corresponds to an increased density of superconducting electrons, so that the composite superconductor can support a larger critical magnetic field strength and a larger critical current density than the constituent bulk superconductor. It also corresponds to a shorter London penetration depth for the composite superconductor, resulting in lower effective conductance at radio frequencies

A structure composed of the composite superconductor medium will have a smaller AC (including RF) resistance than a structure of equal shape that is composed of the constituent bulk superconductor. Thus, for example, a superconducting cavity that is made from the composite superconductor material will have a higher Q than an equivalent superconducting cavity that is made from the constituent bulk superconductor. The structure will also feature a higher crossover frequency than the constituent bulk superconductor, where the crossover frequency is defined as a frequency at which London penetration depth equals normal penetration depth. Thus, for example, a superconducting cavity that is made from the composite superconductor material can be operated at higher frequencies than an equivalent superconducting cavity that is made from the constituent bulk superconductor.

Because the composite superconductor has superconducting properties (critical temperature, critical field strength, etc.) that are more robust than the superconducting properties of an equivalently-shaped bulk superconductor, it will be appreciated that embodiments include deployments of the composite superconductor in any of the contexts in which superconductors are presently used. Large-scale applications include use of the composite superconductor in power cables, power transformers, generators/motors, magnetohydrodynamic propulsors (MHD drives and pumps), energy storage electromagnetics, MRI and particle beam electromagnets, plasma confinement magnets (tokamaks), accelerator cavities, and magnetic bearings or maglevs. Small-scale applications includes use of the composite superconductor in microwave filters, passive microwave devices or resonators, high-Q resonant antennas operating at RF, microwave or terahertz frequencies, far-infrared bolometers, RF/microwave sensors, x-ray detectors, and quantum devices based on Josephson junctions, including SQUID sensors, digital circuits such as rapid single flux quantum (RSFQ) circuits, and superconducting-qubit based quantum computing platforms.

The composite medium can be artificially structured to enhance the phononic density of states by artificially structuring the composite medium as a phononic crystal or by artificially structuring the composite medium as a phononic metamaterial. While distinct theories are used to describe the properties of phononic crystals and phononic metamaterials, the theories are not mutually exclusive and some structures may be fairly described as either phononic crystals or phononic metamaterials.

In general, phononic crystals are artificially-structured composites having a superlattice that is roughly half the phonon wavelength at a frequency of interest. The superlattice spacing can be roughly equal to this half-wavelength spacing, or it can exceed this half-wavelength spacing. The superlattice spacing can also be smaller than this half-wavelength spacing, but if the spacing is sufficiently small, the phononic crystal may be better described as a phononic metamaterial, as discussed below. In the phononic crystal regime, the artificially-structured composite can be structured to provide for hyperbolic dispersion of phonons. In this regime, hyperbolic dispersion arises whenever Bragg scattering effectively prohibits phonon propagation in one direction but allows it in another. This regime is accessible with one-dimensionally-patterned structures, such as alternating layers of two materials. Two-dimensionally-nanopatterned phononic crystals and the connection between their structure and the PDoS is discussed, e.g., in Reference 4. Multiple layers of 2D-nanopatterned structures can form a 3D phononic crystal.

In the phononic metamaterial regime, the superlattice may be described by its effective dynamic elastic constants—dynamic elastic moduli and dynamic density. Whenever such description is possible, this composite medium can be termed a “metamaterial,” or an effective medium. When either the elastic modulus or the dynamic density are extremely anisotropic, to the point where it is positive in one direction and negative in another, the elastic medium becomes an elastically-indefinite medium, i.e. a particular kind of a hyperbolic medium.

In one approach, a phononic metamaterial achieves a negative elastic modulus by providing an elastic resonance. When an elastic resonance has a sufficiently high Q-factor (Q>>1), a negative elastic modulus occurs in a band of frequencies just above the elastic resonance frequency. A resonance of the bulk modulus can be created by a monopolar elastic resonance. A shear modulus resonance can be created by a dipolar elastic resonance (here, the monopolar or dipolar nature of the resonance refers to the distribution of signs of the deformation associated with that normal mode).

Elastic resonances in the phononic metamaterial regime can be created as local resonances, that is, resonances associated predominantly with oscillations inside one period of the metamaterial superlattice. As discussed above, as a local resonance responsible for a hyperbolic phonon dispersion becomes deeply sub-wavelength, the enhancement of the phononic density of states grows as (λ/a)³ for a three-dimensional metamaterial, where a is the superlattice constant; more generally, for a D-dimensional metamaterial, where D>1, the phononic density of states grows as (λ/a)^{D} when the metamaterial is hyperbolic.

Local resonances in the metamaterial regime can be created by virtue of 2D patterning in each layer of a metamaterial. In such implementations, the resonances are the vibrational modes of one or more structural elements within a single unit cell. Reference 5 discusses an example of a 2D-nanopatterned phononic crystal with such localized resonances, which are vibrational modes of silicon nanopillars arranged on a silicon thin film.

One-dimensionally-local resonances can be created in a one-dimensionally periodic lattice, such as a series of alternating materials. While hyperbolic phonon dispersion in 1D superlattices is easier to achieve in the phononic crystal regime, in some cases it is possible to achieve it in the metamaterial regime. In order to achieve phononic resonances at frequencies corresponding to wavelengths much longer than the superlattice period, we envision using two or more materials with vastly different elastic moduli, and/or vastly different density. Reference 2 discusses the use of 1D superlattices composed of negative and positive dielectric constant materials, for the creation of hyperbolic photon dispersion, and the increased photonic density of states in such metamaterials.

The most extreme case of utilizing the large contrast in elastic moduli or dynamic density between the different layers is the use of negative-modulus and/or negative-density metamaterial layers, combined with positive-modulus and positive-density layers of ordinary materials or metamaterials. It is known that the combination of positive- and negative-parameter materials or metamaterials in a unit cell of a superlattice is an efficient way to achieve compact resonators, which resonate at wavelengths much longer than their size.

Designs of negative-modulus or negative-density phononic metamaterials can be modified to transform an omnidirectionally-negative modulus or density into an indefinite or hyperbolic medium, where this negative property is exhibited only for one or some phonon propagation direction, but not all of them. For example, an anisotropic stretch or deformation of an omnidirectionally-negative phononic metamaterial may cause a frequency splitting of the resonances responsible for the negative-parameter band, causing the negative parameter bands to be different depending on the propagation direction. A hyperbolic band thus emerges in the indefinite-medium sub-band formed by the partial overlap of these negative-parameter bands.

In specific implementations of hyperbolic dispersion media, either of phononic crystal or phononic metamaterial nature, it may suffice to achieve hyperbolicity for only one, or only some, but not all, of the phonon dispersion branches that coexist at a given frequency or in a given frequency range. That is because the PDoS is an additive quantity, and a substantial enhancement in the density of states corresponding to a particular phonon type can still amount to an overall increase in the total PDoS.

An illustrative embodiment provides a method of increasing a Cooper pairing instability in a composite medium by artificially structuring the composite medium to enhance a phononic density of states. By artificially structuring the composite medium to increase the phononic density of density of states, the electron-phonon coupling in the composite medium is enhanced, which in turn enhances the Cooper pairing instability in the composite medium, which in turn enhances the superconducting properties (zero temperature energy gap, critical temperature, critical field, etc.) of the composite medium. The artificial structuring can include structuring the composite medium as a phononic crystal or as a phononic metamaterial, as discussed above. The artificially-structured composite can be a binary composite, i.e. a structure of two different materials in one, two, or three dimensions, as illustrated in FIGS. 3A-3C; or the artificially-structured composite can include three or more materials, as illustrated in FIG. 4. The artificial structuring can be achieved by nanofabricating the composite medium according to one or more of the various nanofabrication techniques discussed above.

Another illustrative embodiment provides a method of forming a condensate of Cooper pairs in a composite medium artificially structured to enhance a spectral density of phononic states that contribute to Cooper pairing. The formation of the condensate is a collective action of the electrons in the composite medium, which form a Cooper pair condensate as a consequence of the enhanced electron-phonon coupling in the composite medium. For example, a condensate of Cooper pairs is formed when a composite superconductor, fashioned as described above, is cooled to a temperature below the critical temperature of the composite superconductor, e.g. by placing the composite superconductor in a cryostat, by exposing the composite superconductor to a refrigerant, by placing the composite superconductor in an environment having an ambient temperature less than the critical temperature, etc.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. An apparatus, comprising:
an artificially-structured composite that includes a first material having a first bulk electron-phonon coupling constant; and a second material having a second bulk electron-phonon coupling constant;
where the first and second materials are arranged to provide a composite electron-phonon coupling constant for the artificially-structured composite substantially greater than the first bulk electron-phonon coupling constant or the second bulk electron-phonon coupling constant.

2. (canceled)

3. (canceled)

4. (canceled)

5. (canceled)

6. The apparatus of claim 1, wherein the composite electron-phonon coupling constant is substantially greater than both the first bulk electron-phonon coupling constant and the second bulk electron-phonon coupling constant.

7. (canceled)

8. The apparatus of claim 1, wherein the first material is a first bulk superconducting material having a first bulk superconducting energy gap, and the artificially-structured composite is a composite superconductor having a composite superconducting energy gap greater than the first bulk superconducting energy gap.

9. (canceled)

10. (canceled)

11. The apparatus of claim 1, wherein the first material is a first bulk non-superconducting material, the second material is a second bulk non-superconducting material, and the artificially-structured composite is a composite superconductor.

12. The apparatus of claim 1, wherein the first bulk electron-phonon coupling constant corresponds to a first integrated spectral density of phononic states in a bulk medium of the first material, the second bulk electron-phonon coupling constant corresponds to a second integrated spectral density of phononic states in a bulk medium of the second material, and the composite electron-phonon coupling constant corresponds to a composite integrated spectral density of phononic states in the artificially-structured composite.

13. The apparatus of claim 12, wherein the first and second materials are arranged to introduce a hyperbolic phononic dispersion relation that increases the composite integrated spectral density of phononic states relative to either the first integrated spectral density or the second integrated spectral density.

14. The apparatus of claim 12, wherein the first and second materials are arranged to introduce a van Hove singularity that increases the composite integrated spectral density of phononic states relative to either the first integrated spectral density or the second integrated spectral density.

15. The apparatus of claim 12, wherein the first and second materials are arranged to reduce a phonon group velocity in the artificially-structured composite relative to a phonon group velocity in a bulk medium of either the first material or the second material, whereby to increase the composite integrated spectral density of phononic states relative to either the first integrated spectral density or the second integrated spectral density.

16. The apparatus of claim 13, wherein the first and second materials are arranged to form a phononic crystal.

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. The apparatus of claim 16, wherein a first density of the first material is substantially different than a second density of the second material.

30. The apparatus of claim 16, wherein a first elastic modulus of the first material is substantially different than a second elastic modulus of the second material.

31. (canceled)

32. (canceled)

33. The apparatus of claim 13, wherein the first and second materials are arranged to form a phononic metamaterial.

34. The apparatus of claim 33, wherein the phononic metamaterial defines a unit cell having a lattice constant substantially less than about one-half of a phonon wavelength for a frequency band corresponding to the hyperbolic phononic dispersion relation.

35. The apparatus of claim 33, wherein the phononic metamaterial defines an effective density that is positive in a first direction and negative in a second direction.

36. The apparatus of claim 33, wherein the phononic metamaterial defines an effective elastic modulus that is positive in a first direction and negative in a second direction.

37. (canceled)

38. (canceled)

39. The apparatus of claim 33, wherein the unit cell defines an elastic resonance and the frequency band corresponds to frequencies above a resonant frequency of the elastic resonance and within a negative parameter band of the elastic resonance.

40. The apparatus of claim 39, wherein the negative parameter band is a band of frequencies above the resonant frequency wherein the elastic resonance provides a negative effective density.

41. The apparatus of claim 39, wherein the negative parameter band is a band of frequencies above the resonant frequency wherein the elastic resonance provides a negative effective elastic modulus.

42. A method, comprising:
increasing a Cooper pairing instability in a composite medium by artificially structuring the composite medium to enhance a phononic density of states.

43. The method of claim 42, wherein the artificial structuring of the composite medium includes artificially structuring the composite medium as a phononic crystal.

44. The method of claim 42, wherein the artificial structuring of the composite medium includes artificially structuring the composite medium as a phononic metamaterial.

45. The method of claim 42, wherein the artificial structuring includes nanofabricating the composite medium.

46. (canceled)

47. (canceled)

48. (canceled)

49. The method of claim 42, wherein the artificial structuring of the composite medium includes artificially structuring the composite medium from two or more bulk materials, and at least one of the bulk materials is a bulk superconducting material.

50. (canceled)

51. (canceled)

52. (canceled)

53. (canceled)

54. (canceled)

55. (canceled)

56. (canceled)

57. (canceled)

58. The method of claim 42, wherein the composite medium is composed of non-superconducting bulk materials, and the increasing of the Cooper instability provides the composite medium with a composite superconducting energy gap.

59. The method of claim 42, wherein the artificial structuring to enhance the phononic density of states includes artificially structuring to introduce a hyperbolic phononic dispersion relation.

60. The method of claim 59, wherein the artificial structuring to introduce the hyperbolic dispersion relation includes artificially structuring the composite medium as an indefinite medium.

61. The method of claim 42, wherein the artificial structuring to enhance the phononic density of statues includes artificially structuring to introduce a van Hove singularity to the phononic density of states.

62. The method of claim 42, wherein the artificial structuring to enhance the phononic density of states includes artificially structuring to reduce a phonon group velocity.

63. A method, comprising:
forming a condensate of Cooper pairs in a composite medium artificially structured to enhance a spectral density of phononic states that contribute to Cooper pairing.

64. The method of claim 63, wherein the forming of the condensate of Cooper pairs in the composite medium includes lowering a temperature of the composite below a superconducting critical temperature of the composite medium.

65. The method of claim 63, wherein the composite medium is a phononic crystal.

66. The method of claim 63, wherein the composite medium is a phononic metamaterial.

67. The method of claim 63, wherein the composite medium includes a bulk superconducting material.

68. (canceled)

69. (canceled)

70. (canceled)

71. (canceled)

72. (canceled)

73. (canceled)

74. (canceled)

75. (canceled)

76. (canceled)

77. The method of claim 63, wherein the composite medium is composed of non-superconducting bulk materials.

78. The method of claim 63, wherein the composite medium is artificially structured to enhance the spectral density of phononic states by introducing a hyperbolic phononic dispersion relation.

79. The method of claim 78, wherein the composite medium having the hyperbolic dispersion relation is an indefinite medium.

80. The method of claim 63, wherein the composite medium is artificially structured to enhance the spectral density of phononic states by introducing a van Hove singularity to the spectral density of phononic states.

81. The method of claim 63, wherein the composite medium is artificially structured to enhance the spectral density of phononic states by reducing a phonon group velocity.
